(19) United States
(12) Patent Application Publication
(10) Pub. No.: US 2024/0220362 A1
(43) Pub. Date: Jul. 4, 2024

(54) Fast and Reliable Data Error Correction Methods and Apparatuses

(71) Applicant: Anthony Mai, Menlo Park, CA (US)

(72) Inventor: Anthony Mai, Menlo Park, CA (US)

(73) Assignee: Anthony Mai, Menlo Park, CA (US)

(21) Appl. No.: 18/092,320

(22) Filed: Jan. 1, 2023

(51) Int. Cl. G06F 11/10; H03M 13/11

(52) U.S. Cl. CPC G06F 11/1076; H03M 13/11

(57) ABSTRACT

Current invention provides methods and apparatuses for efficient forward data error correction in communication channels. Said methods and apparatuses can be used to construct highly reliable data communication channels and enable better networking in a broad range of communication application fields, including wired, wireless and optical communication, with distance ranging from inter-chip data link in electronic devices, to long distance and deep space communication.

### CROSS-REFERENCE TO RELATED APPLICATIONS

Provisional Application 63305270, filed on Feb. 1, 2022. This current non-provisional application has no material changed from the said previously filed provisional.

### FIELD OF INVENTION

The current invention is applicable to fields of information technology. Specifically, the current invention provides fast and highly reliable methods and apparatuses for digital data error detection and correction, especially in communication channels. The invention can enable high speed highly reliable communication channels to be established even under the challenge of poor physical signal conditions. The invented methods and apparatuses have lower computation complexity thus perform much faster than legacy forward error correction methods. The current invention also allows fast and reliable data storage systems to be built cost effectively. Possible usage fields include long distance and deep space communications, wired and wireless networks, high speed computer data connections, data storage devices and systems, distributed data storage.

### RELATED PRIOR ARTS

The volume of various digital data in our technology world today is astronomical and grows exponentially every year. Data is processed, transferred and stored. Data storage and communication is a critical part of our technology world today. Data integrity must be protected during communication so that even though a part of the data is received damaged, the error can be detected and fixed so the full and correct data will be received. This protection can be done by inserting extra bits or blocks of data containing redundant information, the receiving end can then use the extra data to check for errors and fix them, using computation methods called forward error correction, or FEC. There are two categories of such data error recovery. The first is called forward error correction, which deals with individual bit errors that are detected but the exact location of the error bits are unknown. Once the precise error bits are determined, the error bits are simply fixed by flipped them between 1 and 0. The second category of error recovery is called forward erasure correction. It deals with erroneous blocks of data. We know location of the error data blocks, but do not know the exact pattern of bit errors, so the error data blocks are assumed to be lost or erased. The erased blocks can be computed from the extra data containing needed repair information.

In typical communication channels, forward error corrections are first applied to data received to fix most bit, and checksum blocks are attached to data packets for integrity check. If a mismatched checksum is found, the data packet has errors and so is erased. But it can still be recovered from extra data packets using forward erasure correction. Combined together, with forward error correction fixing raw bit errors and forward erasure correction repairing erased or dropped data packets, any communication channel can deliver digital data highly reliably.

FEC algorithms have a long history of development since the invention of Hamming Codes in 1950. Today we have Reed-Solomon Codes, invented in 1960, for both the bit error correction and block erasure correction. We have the Viterbi Codes, BCH Codes, Turbo Codes, LDPC (Low Density Parity Check) and Polar Codes for bit level error correction. Researchers even proposed soft decision decoders, using extra information to fix bit errors more accurately.

However all the prior art bit error correction algorithms are complex and have high computation cost. Many of them were invented decades ago. The LDPC was invented in 1963 but forgotten for 33 years due to its impractically high computation complexity, until it was rediscovered in 1996. Today LDPC is one of the major bit error correction algorithms used in high speed networks, with no good replacement in sight. Likewise even though there are plenty of researches to adopt Polar Codes, and put it into one of the standard for 5G wireless networks, the high computation cost prevents wide adoption. Expensive high end micro processors were developed just to handle bit error corrections. Very stringent signal quality requirements are imposed to reduce raw bit error rates to acceptable levels for the FEC algorithms to handle.

Just to give one example of how much is the complexity of existing FEC algorithms; let us have a look at LDPC. The algorithm partitions the data stream into large frames containing many thousands of data bits, extra parity bits are computed from a small set of pseudo randomly picked data bits, and inserted in the data stream. On the receiving end, if the parity bits do not match the computation, it indicates presence of error bits. Determining which bits might be the error bits is a complicated computation using floating point arithmetic and Bayesian statistics based formulas called belief propagation algorithms. The computation often must be repeated 10s or 20s of iterations in order to fix one error bit. As modern network connections push for 100 or even 400 gigabits per second speed, and more complicated signal modulation schemes with high raw bit error rates, existing FEC algorithms simply cannot work fast enough to be practical.

Wireless cellular networks are not the only place requiring bit error corrections. Our inter-continental data traffic goes through ocean-crossing undersea optical fiber cables as light. Light attenuates as it propagates along the fiber. Thus a lot of relay units are needed to boost the signal and fix errors. The high complexity and limited error correction capability of existing FEC algorithms increase the cost and limit the reach and throughput of inter-continental optical fibers.

In summary, the industry desperately needs novel FEC methods that computes fast and fix data errors more effectively, to allow development of next generation communication technology in multiple application fields, including deep space communication, satellite relay and satellite to ground communication, aviation and aerospace communication, cellular networks, IoT wireless networks, industry automation and many more networking application fields.

### SUMMARY OF INVENTION

Present invention provides novel methods and apparatuses for very fast and highly accurate data forward error correction, enabling faster and extremely reliable communication channels to be built even under challenging conditions of poor quality of physical signals.

Any forward error correction scheme must add extra bits and data packets, called parity bits and parity packets. When data is received, the extra information in the parity bits and parity packets help to determine if there is error in the data received, and if there are errors, where are the error bits, so that the errors can be repaired as much as possible. A new FEC scheme must handle production of the parity bits and parity packets differently, and on the receiving end, interprets the parity information in different ways, to allow faster processing.

In examining how FEC algorithms work, we recognize the principle that parity bits and packets only help to identify and fix errors of the data bits or packets that the parity was computed from in the first place. A parity bit or packet contains no information of data bits or packets that it has no dependency on thus can tell us nothing about the unrelated data.

Therefore, we find a weakness in LDPC, Low Density Parity Check, and propose the first novelty of the current. In LDPC data is segregated into frames, error bit correction is done within each frame, not beyond current frame. Each data bit is associated with very few parity bits and each parity bit is associated with very few data bits. Thus the name low density parity check. The sparseness of association is necessary to reduce computation complexity. But it also reduces reliability of error correction. When only a very few parity bits can suggest an error in a data bit, it is unclear whether the data bit is wrong, or the parity bits themselves are wrong, or some other associated data bits could be wrong. This leads to a shortcoming in LDPC, called error floor. It's very difficult to reduce residual bit error rate to below a threshold.

The first novelty of current invention provides an encoding engine which produces a near infinite sequence of parity useful to identify and fix data errors. Thus we no longer use so called low density parity. Instead we have high density parity check. Each of parity has a good chance to help identify and fix any data bit error that occurs before the parity. So there is an infinite chance to fix any data bit error. The chance of an error remains unfixed approaches 0.

The second novelty of the current invention provides fast encoding of parity packets containing multiple parity bits. Individual bits in a parity packet operate in parallel. The parity packets are encoded through an encoding engine using bitwise exclusive or operations. This novelty allows the encoding and decoding operations to operate on one multiple bits packet at a time, instead of one bit at a time, thus the encoding and decoding speed is much faster.

The third novelty of current invention provides a pre-processing method to add check bits to blocks of data. The check bits allow locating and fixing of the simplest bit errors thus reduce the raw bit error rate for the practicality of the next steps of processing. The check bits can be interleaved with the data bits, or can be placed together to form a checksum. Each check bit is the exclusive or of a subset of the data bits. If all check bits match it suggests that the data block is likely correct. Mismatched check bits can be used to form an index for fetching a repair entry from a pre-calculated lookup table, calculated based on statistics. If the repair entry is non-zero, it is applied to repair bits in the data block, which likely results in a corrected data block. This pre-processing step is fast and reduces residual bit errors for the next steps.

The fourth novelty of current invention is the novel methods we use to narrow down likely locations of errors based on whether any repair packet and any of their bits are zero or not, by accumulating confidence scores. When enough confidence scores are accumulated, data packets are either accepted as correct, or identified error bits are fixed.

The fifth novelty of the current invention is the novel methods to recombine repair packets to reduce their dependencies and thus they can more accurately suggest which data packets may contain errors. This makes the error information in repair packets more useful.

This summary only provides an outline of the principles of the present invention and lists the main novelties in a non-exhaustive fashion. The details of the invented process methods and apparatus parts, and practical embodiment examples will be illustrated in the next sections.

Present invention is a non-provisional application as a follow up to a previously filed provisional application. Specific claims are enumerated in the claims section. The main spirit and novelties of the invention, however, are sufficiently stated in this document and also in previously filed provisional application, with no material change since the provisional filing.

### BRIEF DESCRIPTION OF DRA WINGS

This section is skipped as no figure is furnished in this non-provisional application.

### DETAILED DESCRIPTION OF INVENTION

The present invention provides a plurality of data encoding and error correction processing steps and apparatuses to process input data to produce interleaved parity data and to process such interleaved data and parity data to identify and fix bit errors and to deliver original input data correctly. The present invention is useful in helping to build fast and highly reliable communication networks.

As stated in the summary section, there are a few novelties in the current invention:
1. Providing an entropy encoding engine which can produce a near infinite sequence of parity, each one has a good chance to be useful to fix any data bit error that occurs before the parity. See claim 1 step 1c; Claim 2 step 2b; Claim 4; Claim 8 unit 8c; Claim 9 unit 9d and claim 10.
2. Encoding packets of parity bits instead of encoding one parity bit at a time, with individual bits in a parity packet operate in parallel, for fast encoding and decoding throughput speed. See claim 1 step 1c; Claim 2 step 2b; Claim 4; Claim 8 unit 8c; Claim 9 unit 9d and claim 10.
3. Providing a pre-processing method to add check bits to packets of data, allowing repair of the most frequent bit error patterns, reducing the raw bit error rate for the main decoding steps. See claim 1 step 1b; Claim 2 step 2a; Claim 9 unit 9b and 9c; and claim 10.
4. Computing confidence scores of data packets and bits based on whether associated parity packets match or not, and set bits of repair packets calculated, and based on the scores to accept likely correct data packets and repair likely incorrect ones. See claim 2 step 2d and 2e, etc.
5. Recombining repair packets to simplify their dependencies on data packets so they can more specifically suggest which packets may be wrong, making the error information more useful. See claim 5 and see further explanations as follows.

The details of these novelties and example embodiments will be discussed next.

### Basic Principles of Current Invention

The first novelty of the current invention is that an entropy encoding engine is used which is capable of producing an infinite sequence of parity symbols, after original data symbol information is encoded and persisted in the encoding engine. This contrasts against not just the LDPC, but all other prior art FEC schemes, where each data bit is related to very few parity bits, and each parity bit is related to very few data bits, resulting in limited chance of cross-checking to fix errors reliably. As the invented encoding engine continuous to produce a sequence of parity symbols with good chance of correlated to any data symbols in question, any symbol errors are exposed by subsequent parity symbols repeatedly, until they are eventually fixed. Sec claim 4 and see further explanations to follow.

The invented entropy encoding engine stores N data symbols. All symbols have the same size, which can be one or many bits. Bitwise exclusive or operations are used in the engine. It can carry out three types of operations: input a data symbol; update; output a parity symbol. In each of operation iteration, one data input and one update is performed, but output parity symbol is performed only when needed, depending on the desired parity to data ratio. For data symbol input, the input symbol is exclusive or into a subset of the symbols stored in the engine. For the update, symbols are rotated, and some symbols are exclusive or into other symbols. Note that all operations are just a series of atomic exclusive or operations, with one symbol exclusive or unto another symbol, a reversible step. Since the steps are reversible, entropy stored in the engine do not change. This is why the engine can continue indefinitely to emit parity symbols correlated to previous data symbols. Two copies of the same engine operate both on the sender side and on the receiver side. If all data is received without error, the sender and receiver engine will produce matching parity symbols. If the parity symbols do not match, the exclusive or between them, called repair symbols, are non-zero, and they help to identify and fix the errors.

In the second novelty of the current invention, multiple bit symbols are used in the above-mentioned entropy engine. For example a symbol can contain 4096 bits or 512 bytes. This allows faster processing, as the engine will process multiple bits instead of just one bit at a time. Sec claim 1 step 1a and claim 3. Note a coded symbol block contains both data and parity bits.

In the third novelty of the current invention, an extra encoding stage is added to reduce raw bit error rate. The way it works is that raw input data is first processed by above mentioned entropy encoding engine and separated into data symbols with some generated parity symbols mixed in, depending on the parity to data ratio. Then the encoded data pass through a second stage of encoding, which can be a legacy bit error correction scheme like BCH or Reed-Solomon or LDPC, but can also be a novel checksum as provided by the current invention. See claim 3. For example, a simple 24 bits checksum can be calculated from 128 bits of data. The checksum can detect most errors, and allow the most frequent simple bit errors to be fixed, thus reducing the remaining bit error rate. On the receiver side, the same checksum is computed and compared to see if they match or not. If they mismatch, the exclusive or value between the two checksums is used to index into a lookup table to find simple bit error fixes. After the initial processing, some data errors can remain but the error rate is lower for main decoder to process.

In the fourth novelty of the current invention, a receiver computes repair symbols by bitwise exclusive or received parity symbols against the locally generated ones. See claim 2 step 2b. Since the same encoding engine runs both on the sender side and the receiver side, the two parity symbols should be identical and thus the calculated repair symbols are zero. Whether any repair symbols are zero or not, and if they are not zero, the non-zero bits in the repair symbols provide useful information to determine location of error symbols and error bits. The current invention provides novel method to use this information to find and fix the data errors.

In one embodiment example, a numerical confidence score is used to represent the likelihood that a data symbol is likely wrong, and each bit can also have a score of how likely the bit is in error. For example, a logarithm score of 0 means that there is equal possibility there is error or not. A score of 1.0 means there is 21.0, or 2 times likelihood there is error, than there is not. A score of −1.0 means there is 2-1.0, or half likelihood there is error, versus there is not. In other embodiment examples, traditional statistical calculations, called belief propagation, can be carried out to compute the confidence score. See claim 7 and step 7c.

Thus, for example, when a repair symbol is computed to be zero, and it correlates to ten recent data symbols, there is a very high chance that all ten data symbols have no error, with a much lower chance that at least two symbols have error, and their errors happen to cancel out, resulting in a zero repair symbol. So, we lower the score of each data symbols by 8, to account for that there is 2\hat{ }8=256 times less odd of having errors than not having errors. Likewise, when a repair symbol is non-zero, the non-zero bits in it suggest corresponding bits in correlated data symbols are more likely to be wrong, so the scores of such data bits are raised accordingly.

When scores of data bits become significant, these data bits are likely wrong so they are flipped to correct the errors. When a data symbol reaches such a low score there is virtually no chance it still contains error, the symbol is accepted as correct and thus no longer considered for any further processing. And the processing moves forward to subsequent data symbols.

After such processing there should be no more non-zero repair symbol, suggesting there are no more detected errors. If there are still detected errors, the data is processed again using the same processing steps, to eradicate any remaining data errors.

While the fourth novelty provides good methods to identify and fix data errors based on whether repair symbols are zero or not, and based on correlations between data symbols and repair symbols, it can get difficult trying to pin-point which data symbols may have errors, as more repair symbols are processed, and each repair symbol can correlate to a lot data symbols.

The fifth novelty of the current invention solves this problem by providing a method to recombine repair symbols, so that the recombined repair symbols have fewer data symbols correlated to them. See claim 5 and especially step 5d. The fewer correlations make it easier to locate data errors because the search space is narrowed. This can be achieved by recombining the repair symbols so that for each bit in the repair symbols, no more than one repair symbol has that bit as 1. The same bit in all the other recombined repair symbols should be 0.

An example embodiment example takes the following steps to achieve such a result. First we ensure the first data bit in the first repair symbols is set. If not we search in the rest of the repair symbols to see if anyone has that bit set. If we find one, the repair symbol is exclusive or unto the first repair symbol, so now it has its first bit set. If no repair symbol has that bit set, then we skip the first bit and examine the second bit instead. Second, with the first repair symbol carries the first bit as 1, we ensure that the same bit is 0 in all other repair symbols. For anyone having the same bit as 1, we exclusive or the first repair symbol into it to cancel out the set bit.

This processing is repeated for all current processing repair symbols. Eventually we have a few non-zero repair symbols correlated to very few data symbols, and a lot more repair symbols with zero value which are correlated to a lot of error free data symbols. This facilitate using the fourth novelty methods to pinpoint and repair data symbols with errors, and using the zero value repair symbols to clear data symbols as likely error-free and need no more processing.

There can be a lot of variations in practical embodiments without deviating from the spirit of the five novelties as explained above. All such variations of practical embodiments are considered included and incorporated in the current invention.

1. A method of processing input data to produce a plurality of coded blocks to be used to recover from future data corruption and loss and recover the original input data, when said code blocks are received later or remotely, in a multiple stage encoding process, comprising steps of:
1a. Partitioning input data into a plural of raw data blocks of equal bit size, with padding bits and size information inserted as necessary to make the final raw data block a full block;
1b. Computing and appending a set of parity bits for each raw data block to produce a coded block, containing raw payload data bits and parity bits, with same size of coded blocks;
1c. Processing coded blocks sequentially by a coding engine with a buffer to emit parity blocks of the same size on a schedule according to a desired parity/data block ratio;
1d. Making the coded blocks and parity blocks available sequentially, with their sequence numbers, for transfer to a different spacetime location and for later data recovery from errors.

2. A method of processing received coded and parity blocks in according to claim 1, to recover from data errors losses and produce the original input data completely and correctly, comprising steps of:
2a. Processing each received coded and parity blocks to recover some bit errors based on mismatched parity bits contained in said blocks. Lost coded blocks are replaced with a block containing all 0 bits. Lost parity blocks are omitted from subsequent processing;
2b. Processing coded blocks from step 2a by an identical coding engine as in step 1c to emit local parity block according to the same schedule in step 1c, with each local parity block exclusive or with the corresponding received parity block if available, to produce a repair block. Such produced repair blocks shall contain all 0 bits if there was no error in received blocks;
2c. Obtaining correlation relation bit maps based on relative positions of bits in coded and parity blocks, and the repair bits in available repair blocks produced in step 2b;
2d. Identify and fix possible error bits based on correlation bit map obtains in step 2c. based on the idea that a bit that is correlated to more set repair bits and fewer zero repair bits, is more likely to be an error bit, and thus should be fixed by flitting the bit between 0 and 1;
2e. Repeating step 2d until all parity bits in a coded block match, and all related repair bits are zero in the repair blocks closely following said coded block in their sequence numbers. Repeat step 2a for some coded blocks as necessary if parity bits in said block are mismatched;
2f. Extracting the raw data payload bits in a leading coded block once all related errors are fixed as in step 2e, and making said error-fixed raw data available based on the sequence number.

3. A method of computing parity bits according to claim 1 step 1a and claim 2 step 2a, comprising of steps:
3a. Choosing a reasonable number of raw data bits and number of parity bits in each block;
3b. Choosing an encoding parameter based on number of parity bits decided in step 3a;
3c. Processing each raw data block using the same parameter chosen in step 2a to produce the parity bits for said data block, and combining the data bits and parity bits into a coded block.

4. A method of computing parity blocks according to claim 1 step 1c and claim 2 step 2b and claim 3 step 3a, by a coding engine, comprising steps of:
4a. Choosing a reasonable buffer size N of said coding engine, with said buffer suitable to contains number N of coded blocks, with each block containing the number of bits as in step 3a;
4b. Choosing an encoding parameter based on the number N, for ingestion of coded blocks and transforming blocks stored in the buffer by rotation, and exclusive or of selected blocks;
4c. Processing each coded block by ingesting it in according to chosen parameter in step 4b, and emitting a parity block based on a chosen schedule based on desired parity/data ratio;
4d. Making emitted parity blocks available with the corresponding sequence numbers, along with the coded blocks, for delivery to a receiver at a different spacetime point.

5. A method of computing repair blocks, according to claim 2 step 2b, comprising step 2b and 2c and further steps:
5a. Processing a received parity blocks based on step 2a and 2b to produce repair blocks.
5b. Obtaining bit correlation bit map for a repair block based on step 2c;
5d. Further simplifying the correlations obtained in step 5b, by exclusive or selected repair blocks and the correlation bit maps, to produce repair blocks with fewer and simpler correlations;
5e. Proceeding to the further processing steps according to step 2d, 2e and 2f.

6. A method of error bit correction in accordance to claim 2 and claim 5, where determination of error bits in steps 2a, 2d, 5a and 5e is improved by further steps:
6a. Obtaining information of the likelihood of a bit being correct or error, from a receiver's signal demodulation unit which turns physical received signal into raw digital data bits 0 or 1;
6b. Using the bit confidence information obtained in step 6a to identify likely error bits based on count of correlated parity bits that are mismatched or matched, according to claim 2, 5.

7. A method of error bit correction in accordance to claim 2, 5, 6, where determination of error bits in steps 2a, 2d, 5a, 5e and 6b is further improved by further steps:
7a. Identifying all correlated received bits for each repair bits computed, where a 0 repair bit suggests either there is no error, or there is an even number of errors in correlated bits thus the error cancels out, and a non-zero repair bits suggest existence of an odd number of errors within said correlated bits;
7b. Compute an initial confidence score for each received bit in question, said confidence score reflect the likelihood that the bit in question is in error, according to previously stated steps;
7c. Repeatedly adjusting confidence score for each bit in question, based on the correlation as obtained in step 7a, based on the mathematics of probability statistics.

8. An apparatus according to claim 1, comprising parts of:
8a. A unit that receives input data and partition data into raw data blocks;
8b. A unit that processed a raw data block containing a number of bits, to produce a number of parity bits, and to combine data bits and parity bits into a coded block;
8c. A coding unit that contains a memory buffer and takes input of a coded block, transforms blocks stored in the memory buffer, and may emits a parity block as needed;
8d. A unit to assign sequence numbers to produced coded and parity blocks and to make them available for physical delivery to a different spacetime point.

9. An apparatus according to claim 1, claim 2 and claim 8, comprising some parts as in claim 8 and comprising further parts of:
9a. A unit that receives coded or parity blocks with their sequence numbers, as delivered by an apparatus constructed in accordance to claim 8;
9b. A unit to separate received coded or parity blocks to data bits and parity bits, and produces local parity bits in accordance to unit 8b, and exclusive or said local parity bits with received parity bits to produce intra block repair bits, with any such repair bit being 1 indicates existence of error bits within the block;
9c. A unit to quickly identify and fix some likely error bits in a received block, based on repair bits produced from unit 9b. Said received coded or parity block is further processed by;
9d. A coding unit same as unit 8c, that processes initially fixed coded blocks, and produces a local parity block corresponding to each received and initially fixed parity block;
9e. A unit to exclusive or a locally produced parity block from unit 9d, with a received parity blocked initially fixed by the unit 9c, to produce a repair block. Any set bit in said repair block indicate existence of errors in correlated coded or parity block;
9f. A unit to obtain block correlation bit map, based on relative sequence numbers of the coded and parity blocks in question, according to the coding unit 9d;
9g. A unit to determine likelihood of bit error, for each received bit in coded and parity block, based on correlation bit maps received from unit 9f and repair bits from unit 9e. The unit further fix a likely error bit by flipping it between 0 and 1. The unit operates until a coded block's vicinity repair bits are reset to 0 in the repair blocks with close sequence numbers;
9h. A unit to repeat processing in unit 9c to eliminate remaining errors, and make the payload data bits from coded blocks available sequentially based on their sequence numbers.

10. An apparatus according to claim 9, comprising all parts of claim 9 and further enhance of additional processing parts in accordance to claim 6 and claim 7, comprising:
10a. All units in accordance to claim 9, and in addition;
10b. A unit to obtain bit confidence information from a received signal demodulator;
10c. A unit for statistical probability computation, according to claim 7 step 7c;
10d. A unit according to unit 9g, with further improvement to computation based on information obtained from units 10b and 10c, and a part to control number of computation iterations and release of payload bits from a data block as fully processed and error fixed.
